(19) United States
(12) Patent Application Publication
(10) Pub. No.: US 2018/0119269 A1
(43) Pub. Date: May 3, 2018

(54) MASK FOR DEPOSITING OLED PANEL

(71) Applicant: HON HAI PRECISION INDUSTRY CO., LTD., New Taipei (TW)

(72) Inventor: YASUHIRO MIZUNO, New Taipei (TW)

(21) Appl. No.: 15/791,244

(22) Filed: Oct. 23, 2017

Related U.S. Application Data
(60) Provisional application No. 62/413,447, filed on Oct. 27, 2016.

(51) Int. Cl. C23C 14/04; C23C 14/12; H01L 51/00; H01L 51/56

(52) U.S. Cl. CPC C23C 14/042; C23C 14/12; H01L 27/3244; H01L 51/56; H01L 51/0011

(57) ABSTRACT

A mask for depositing a precise OLED layer as pixels on a substrate includes a frame, a main film, and a supporter. The frame defines a first opening extending through the frame. The main film is fixed on the frame and covers the first opening. The main film defines a plurality of second openings. The main body includes a plastic film. Each second opening extends through the plastic film and air communicates with the first opening. The supporter is fixed on the frame and in the first opening. The frame and the supporter cooperatively support the main film to reduce shadow effect.

### FIELD

The subject matter herein generally relates to a mask, and particularly relates to a mask for depositing an organic light emitting layer on a substrate.

### BACKGROUND

A method for making an organic light emitting diode (OLED) display panel generally includes forming an organic light-emitting material layer on a substrate (e.g., a thin film transistor substrate) by vapor deposition. A mask is used during the formation of the organic light-emitting material layer on the substrate and the mask is positioned on the substrate. The mask defines a plurality of through holes, thus evaporated material from an evaporation source can pass through the through holes and be deposited on the substrate. The organic light-emitting material deposited on the substrate by each through hole defines a sub-pixel of the OLED display panel. Typically, a size of each through-hole is designed to be equal to a desired size of a sub-pixel. However, a size of the sub-pixel formed by using the mask is often greater than the desired size of the sub-pixel because of gaps between the mask and the substrate during the deposition process. This phenomenon is called the shadow effect.

### BRIEF DESCRIPTION OF THE DRAWINGS

Implementations of the present technology will now be described, by way of example only, with reference to the attached figures.

FIG. 1 is a planar view of a first exemplary embodiment of a deposition mask.

FIG. 2 is a cross-sectional view of the deposition mask along line II-II of FIG. 1.

FIG. 3 is a cross-sectional view of a first exemplary embodiment of a main film of a deposition mask of FIG. 1.

FIG. 4 is a cross-sectional view a second exemplary embodiment of a main film of a deposition mask of FIG. 1.

FIG. 5 is a cross-sectional view of the deposition mask of the first embodiment and a substrate.

FIG. 6 is a planar view of a second exemplary embodiment of a deposition mask.

FIG. 7 is a planar view of a third exemplary embodiment of a deposition mask.

FIG. 8 is a planar view of a fourth exemplary embodiment of a deposition mask.

FIG. 9 is a planar view of a fifth exemplary embodiment of a deposition mask.

FIG. 10 is a planar view of a sixth exemplary embodiment of a deposition mask.

FIG. 11 is a planar view of a seventh exemplary embodiment of a deposition mask.

FIG. 12 is a planar view of an eighth exemplary embodiment of a deposition mask.

FIG. 13 is a cross-sectional view of the deposition mask along line XIII-XIII of FIG. 8.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

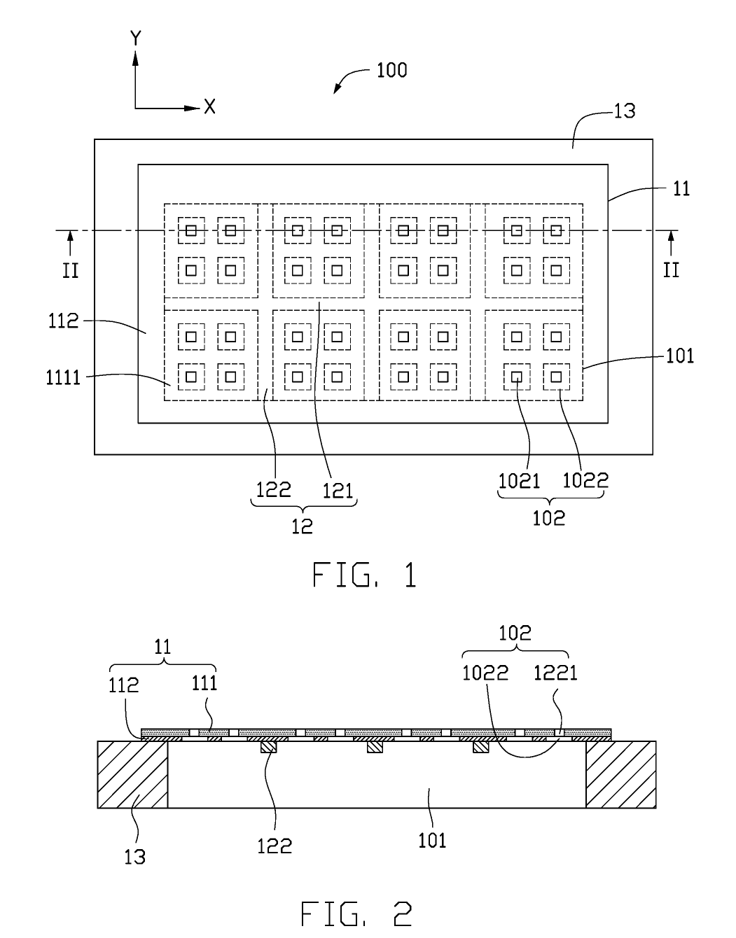

FIG. 1 and FIG. 2 illustrate a deposition mask 100 according to a first exemplary embodiment. The deposition mask 100 can be used in a process of forming an organic light-emitting layer on a substrate.

As shown in FIG. 1 and FIG. 2, the deposition mask 100 includes a main film 11, a supporter 12, and a frame 13. The frame 13 defines a first opening 101. In this exemplary embodiment, the first opening 101 is substantially rectangular, but the shape of the first opening 101 is not limited to rectangular. In other embodiments, the first opening 101 may have other shapes, such as a circle, a rhombus, and etc. The main film 11 is fixed on the frame 13 and completely covers the first opening 101. The frame 13 is configured as a carrier on which the main film 11 is loaded. The supporter 12 is fixed on the frame 13 and coupled to the main film 11. The frame 13 and the supporter 12 are coupled on a same surface of the main film 11.

The frame 13 only covers a periphery of the main film 11. Other portions of the main film 11 corresponding to the first opening 101 can be supported by the supporter 12. In this exemplary embodiment, the supporter 12 includes at least one first supporting portion 121 and at least one second supporting portion 122. Each first supporting portion 121 extends along an X direction; and each second supporting portion 122 extends along a Y direction. Each first supporting portion 121 intersects with the second supporting portion 122. Each first supporting portion 121 crosses the first opening 101 and has two first ends fixed to the frame 13. Each second supporting portion 122 crosses the first opening 101 and has two second ends fixed to the frame 13. The at least one first supporting portion 121 and the at least one second supporting portion 122 are configured to support the main film 11.

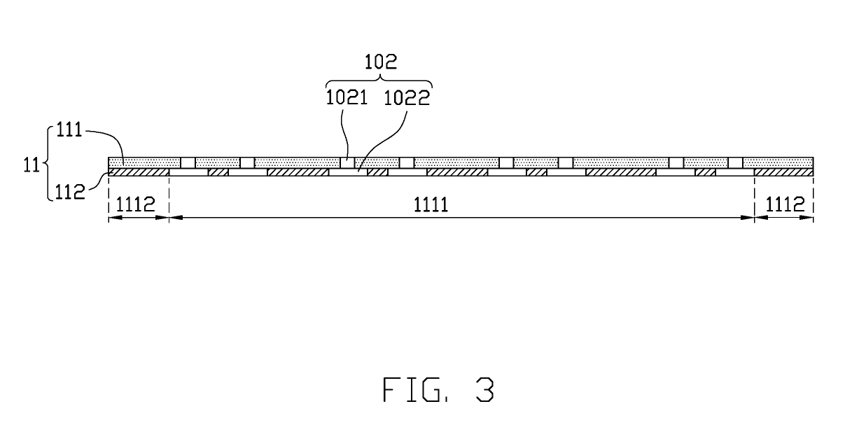

FIG. 3 illustrates a main film 11 according to a first exemplary embodiment. The main film 11 includes a metal film 112 and a plastic film 111 stacked on the metal film 112. The main film 11 defines a central region 1111 and a peripheral region 1112 surrounding the central region 1111. The main film 11 defines a plurality of second openings 102 in the central region 1111. In this exemplary embodiment, the second openings 102 are arranged in an array. Each second opening 102 extends through the main film 11. Each second opening 102 extends through both the metal film 112 and the plastic film 111. Each second opening 102 includes a first sub-opening 1021 extending through the plastic film 111 and a second sub-opening 1022 extending through the metal film 112. The first sub-opening 1021 aligns with the second sub-opening 1022. An inner diameter of the second sub-opening 1022 is greater than an inner diameter of the first sub-opening 1021.

As shown in FIG. 2, each second opening 102 air communicates with the first opening 101. The metal film 112 is in direct contact with the frame 13 and the supporter 12, and the metal film 112 is between the plastic film 111 and the frame 13.

A projection of the supporter 12 on the main film 11 does not overlap with the plurality of second openings 102. As shown in FIG. 1, the number of the first supporting portions 121 is one, and the number of the second supporting portions 122 is three. The two first ends of each first supporting portion 121 and the two second ends of each second supporting portion 122 can be fixed on the frame 13 by soldering. For example, a plurality of grooves (not shown) may be defined in the frame 13, and the two first ends of each first supporting portion 121 and the two second ends of each second supporting portion 122 can be accommodated in the grooves so that each first supporting portion 121 and each second supporting portion 122 can cross the first opening 101 of the frame 13.

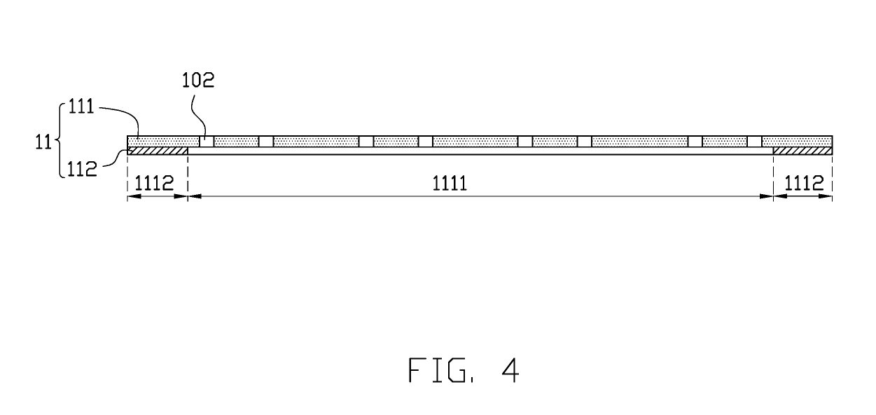

FIG. 4 illustrates a main film 11 according to a second exemplary embodiment. The main film 11 includes a plastic film 111 and a metal film 112. The metal film 112 is coupled to a peripheral portion of the plastic film 111. The main film 11 defines a central region 1111 and a peripheral region 1112 surrounding the central region 1111. The metal film 112 is located in the peripheral region 1112. The main film 11 defines a plurality of second openings 102 in the central region 1111. In this exemplary embodiment, the second openings 102 are arranged in an array. Each second opening 102 extends through the plastic film 111.

In other embodiments, the metal film 112 may be removed and the main film 11 may only include the plastic film 111.

When depositing an organic light-emitting layer of the OLED display panel on a substrate, the deposition mask and a substrate (e.g., a thin film transistor substrate) are placed in a deposition apparatus (e.g., a vapor deposition machine, not shown) having a magnetic plate (not shown); and the substrate is stacked between the magnetic plate and the deposition mask. If the mask is magnetic, attraction between the mask and the magnetic plate brings and keeps the mask and the substrate close together. As shown in FIG. 5, the substrate 14 is stacked on a side of the main film 11 away from the supporter 12 and the frame 13 during the deposition, particularly stacked on a side of the plastic film 111 away from the supporter 12 and the frame 13. Evaporated material from an evaporation source can pass through the first opening 101 and the second openings 102 and be deposited on the substrate 14. The metal film 112 is magnetic, thus the main film 11 is attracted to the substrate 14. The supporter 12 and the frame 13 may also be magnetic.

The metal film 112 may be made of at least one selected from a group consisting of cobalt (Co), nickel (Ni), iron (Fe), titanium (Ti), and invar alloy, but is not limited to the above materials. The thickness of the metal film 112 is between about 5 μm and about 50 μm.

The supporter 12 may be made of at least one selected from invar alloy, nickel, and stainless steel, but is not limited to the above materials. The frame 13 may be made of at least one selected from invar alloy, nickel, and stainless steel, but is not limited to the above materials.

The plastic film 111 may be made of at least one selected from a group consisting of polyethylene terephthalate (PET), polycarbonate (PC), polyethylene (PE), polyether ether ketone (PEEK), polyetherimide (PE), polyimide (PI), polyamide (PA), polytetrafluoroethylene (PTFE), polypropylene (PP), polyphenylene sulfide (PPS), but is not limited to the above materials. The thermal expansion rate of the plastic film 111 is between 1.0 ppm/K and 15.0 ppm/K. The thickness of the plastic film 111 is between about 3 μm and about 100 μm.

Generally, a conventional deposition mask may deform during the vapor deposition process, and a distance may appear between the deposition mask and the substrate to be deposited. The distance is called the bending deflection. In this disclosure, the main film 11 has a bending deflection of less than about 80 μm due to the presence and structures of the frame 13 and the supporter 12. Specifically, since the distance between the deposition mask 100 and the substrate 14 is reduced, the evaporated materials can be accurately deposited at the positions of the substrate 14 corresponding to the second openings. Thus, the shadow effect can be effectively reduced or avoided.

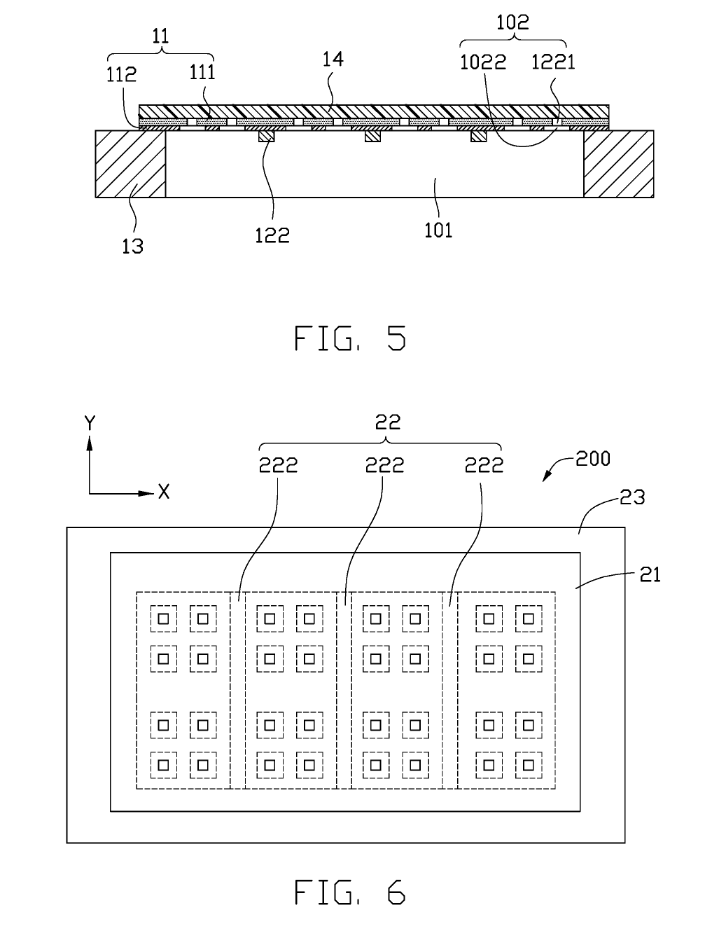

FIG. 6 illustrates a deposition mask 200 according to a second exemplary embodiment. The deposition mask 200 is substantially the same as the deposition mask 100 of the first exemplary embodiment. The deposition mask 200 has a main film 21 that is the same as the main film 11 in FIG. 1 and a frame 23 that is the same as the frame 13 in FIG. 1. The deposition mask 200 also has a supporter 22, the supporter 22 only includes a plurality of supporting portions 222 extending along a Y direction. In one exemplary embodiment, distances between every two adjacent supporting portions 222 are equal.

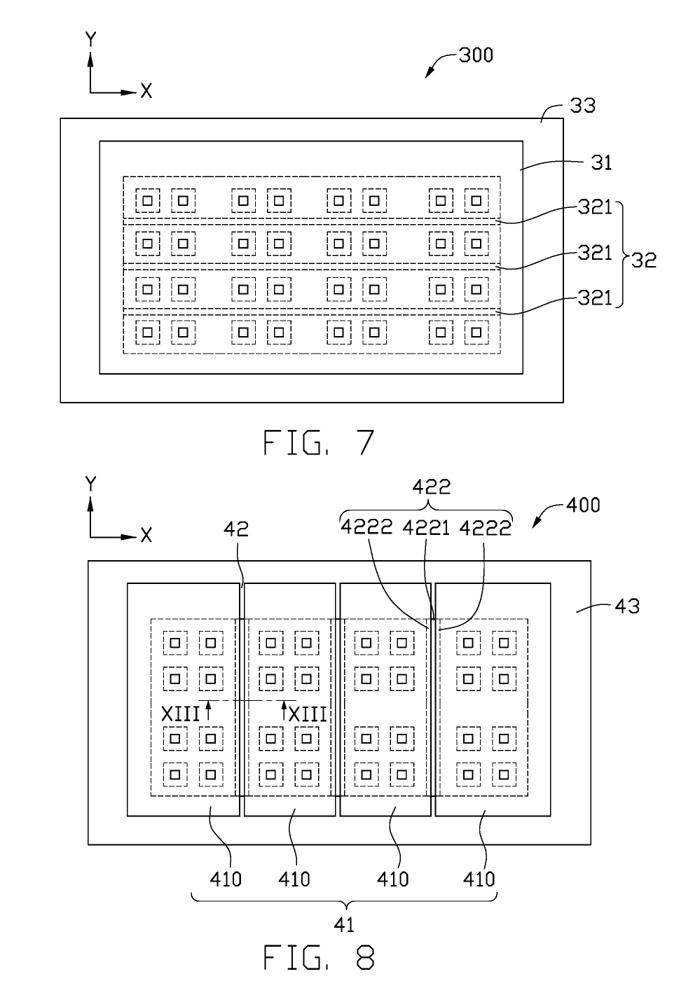

FIG. 7 illustrates a deposition mask 300 according to a third exemplary embodiment. The deposition mask 300 is substantially the same as the deposition mask 100 of the first exemplary embodiment in FIG. 1. The deposition mask 300 has a main film 31 that is the same as the main film 11 and a frame 33 that is the same as the frame 13. The deposition mask 300 also has a supporter 32 and the supporter 32 only includes a plurality of supporting portions 321 extending along an X direction. In one exemplary embodiment, distances between each two adjacent supporting portions 321 are equal.

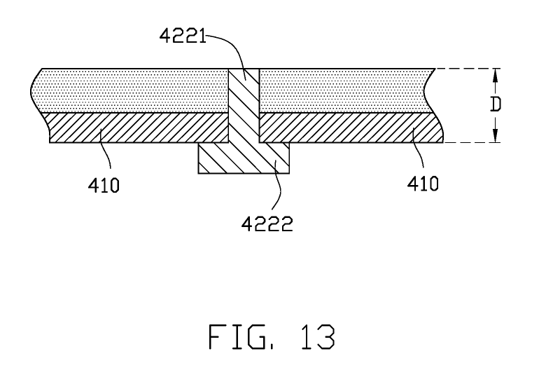

FIG. 8 and FIG. 13 illustrate a deposition mask 400 according to a fourth exemplary embodiment. As shown in FIG. 8, the deposition mask 400 has a main film 41, a supporter 42, and a frame 43. The frame 43 is the same as the frame 13 in FIG. 1. The supporter 42 includes a plurality of supporting portions 422 extending along a Y direction. The main film 11 in FIG. 1, the main film 21 in FIG. 6, and the main film 31 in FIG. 7 are continuous as layers. The main film 41 is a discontinuous layer and includes at least two sub-layers 410 spaced apart from each other. As shown in FIG. 13, each supporting portion 422 includes a main portion 4222 and an extending portion 4221 extending from the main portion 4222. The main portion 4222 of each supporting portion 422 supports the adjacent two sub-layers 410, the extending portion 4221 of each supporting portion 422 is located between two adjacent sub-layers 410 to separate the two adjacent sub-layers 410. In the exemplary embodiment, a width of the main portion 4222 is greater than a width of the extending portion 4221; and the width direction is perpendicular to a thickness direction (thickness D) of the sub-layers 410. In the exemplary embodiment, the thickness of the extending portion 4221 is equal to the thickness D of the main film 41, and the first extending portion 4221 is flush with the main film 41. In other embodiments, the thickness of the extending portion 4221 may be smaller than the thickness D of the main film 41. The supporter 42 and the frame 43 cooperatively support the main film 41.

Specifically, each sub-layer 410 is supported by a main portion 4222 of one corresponding supporting portion 422 and the frame 43. In the exemplary embodiment, the main film 41 is divided into a plurality of sub-layers 410 by the extending portion 4221 of each supporting portion 422, which effectively reduces deformation of the deposition mask 400.

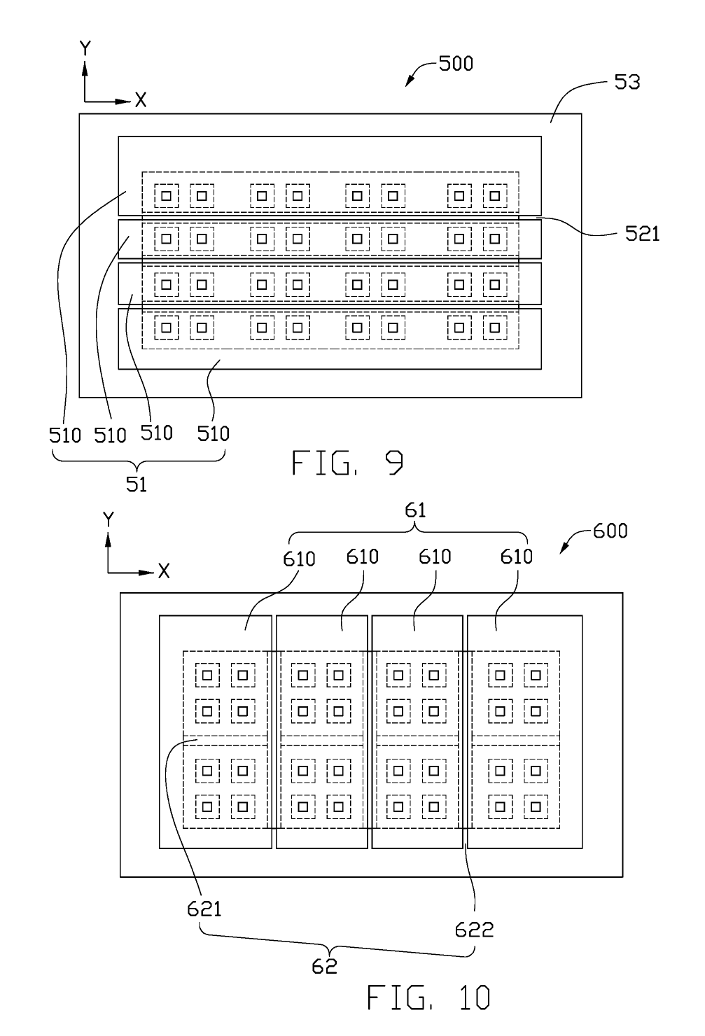

FIG. 9 illustrates a deposition mask 500 according to a fifth exemplary embodiment. The deposition mask 500 is substantially the same as the deposition mask 400 of the fourth exemplary embodiment. The deposition mask 500 has a main film 51 that is the same as the main film 41 in FIG. 8, a frame 53 that is the same as the frame 43 in FIG. 8, and a supporter 52. The supporter 52 includes a plurality of supporting portions 521, each is substantially the same as supporting portion 422, except that each supporting portion 521 extends along an X direction, while each supporting portion 422 extends along a Y direction. The main film 51 is divided into a plurality of sub-layers 510 by the supporting portions 521.

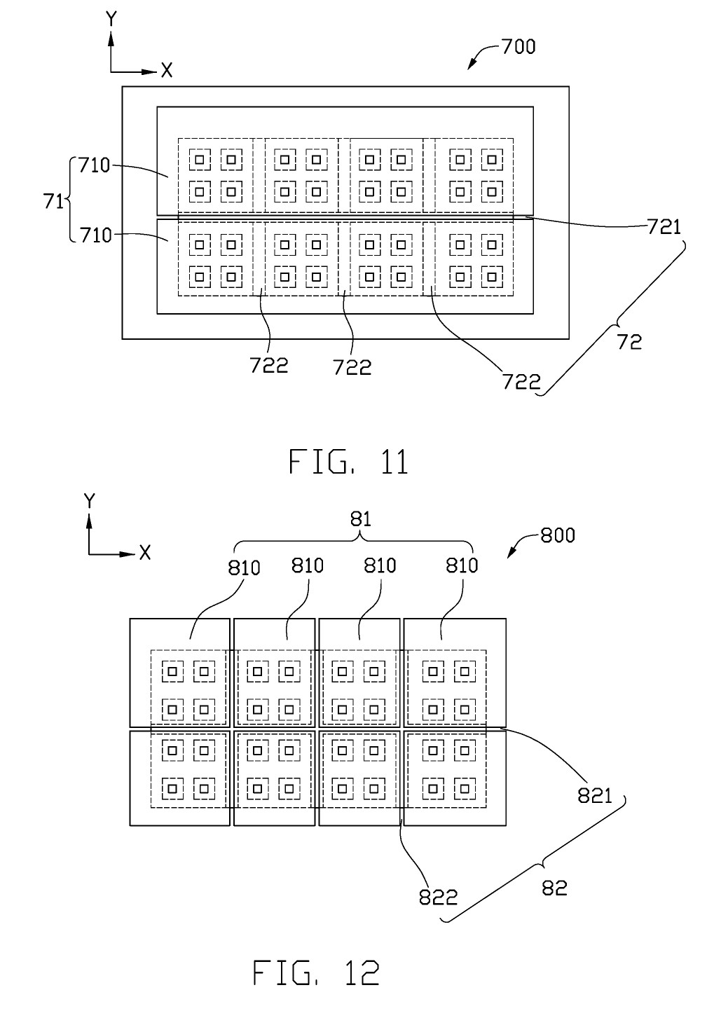

FIG. 10 illustrates a deposition mask 600 according to a sixth exemplary embodiment. The deposition mask 600 is substantially the same as the deposition mask 400 of the fourth exemplary embodiment, except that the deposition mask 600 has a supporter 62 that includes not only a plurality of second supporting portions 622 that are each the same as the supporting portion 422, but also at least one first supporting portion 621. Each first supporting portion 621 extends along an X direction. Each first supporting portion 621 is the same as the first supporting portion 121. The main film 61 of the deposition mask 600 is divided into a plurality of sub-layers 610 by the at least one second supporting portions 622. In the exemplary embodiment, there is one first supporting portion 621 and three second supporting portions 622.

FIG. 11 illustrates a deposition mask 700 according to a seventh exemplary embodiment. The deposition mask 700 is substantially the same as the deposition mask 500 of the fifth exemplary embodiment in FIG. 9, except that the deposition mask 700 has a supporter 72. The supporter 72 includes not only a plurality of second supporting portions 722 that are the same as the second supporting portions 122, but also at least one first supporting portion 721. Each first supporting portion 721 extends along a Y direction. Each first supporting portion 721 is the same as a supporting portion 521. The main film 71 of the deposition mask 700 is divided into a plurality of sub-layers 710 by the at least one first supporting portion 721. In the exemplary embodiment, there is one first supporting portion 721 and three second supporting portions 722.

FIG. 12 illustrates a deposition mask 800 according to an eighth exemplary embodiment. The deposition mask 800 is substantially the same as the deposition mask 700 of the seventh exemplary embodiment, except that the deposition mask 800 has a supporter 82. The supporter 82 includes not only at least one first supporting portion 821 that is the same as first supporting portion 721 but also a plurality of second supporting portions 822. Each second supporting portion 822 is the same as a second supporting portion 422. The main film 81 of the deposition mask 800 is divided into a plurality of sub-layers 810 by the at least one first supporting portion 821 and the plurality of second supporting portions 822. In the exemplary embodiment, there is one first supporting portion 821 and three second supporting portions 822.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A mask comprising:
a frame, the frame defining a first opening extending through the frame;
a main film, the main film fixed to the frame and covering the first opening, the main film defining a plurality of second openings, the main body comprising a plastic film, each of the plurality of second openings extending through the plastic film and air communicating with the first opening; and
a supporter, the supporter fixed to the frame and in the first opening;
wherein the frame and the supporter cooperatively support the main film.

2. The mask of claim 1, wherein both the supporter and the frame are coupled on a same surface of the main film.

3. The mask of claim 2, wherein the main film further comprises a metal film stacked on the plastic film, each of the plurality of second openings extends through the metal film.

4. The mask of claim 3, wherein each of the plurality of second openings comprises a first sub-opening extending through the plastic film and a second sub-opening extending through the metal film, an inner diameter of the second sub-opening is greater than an inner diameter of the first sub-opening.

5. The mask of claim 3, wherein the metal film is made of a magnetic metal or a magnetic alloy.

6. The mask of claim 3, wherein both the supporter and the frame are coupled on a surface of the metal film away from the plastic film.

7. The mask of claim 2, wherein the main film further comprises a metal film coupled to the plastic film; the main film defines a central region and a peripheral region surrounding the central region, the plurality of second openings is in the central region, and the metal film is in the peripheral region.

8. The mask of claim 7, wherein the metal film is made of a magnetic metal or a magnetic alloy.

9. The mask of claim 1, wherein the supporter comprises at least one supporting portion; each of the at least one supporting portion extends along a same direction and crosses the first opening, each of the at least one supporting portion comprises two ends fixed to the frame.

10. The mask of claim 9, wherein the main film is a discontinuous layer and comprises at least two sub-layers; each of the at least one supporting portion comprises a main portion and an extending portion extending from the main portion; the main portion supports two adjacent sub-layers, the extending portion locates between two adjacent sub-layers to separate the two adjacent sub-layers.

11. The mask of claim 10, wherein a width of the main portion is greater than a width of the extending portion.

12. The mask of claim 1, wherein the supporter comprises at least one first supporting portion and at least one second supporting portion; each of the at least one first supporting portion extends along a first direction and crosses the first opening, each of the at least one first supporting portion comprises two first ends fixed to the frame; each of the at least one second supporting portion extends along a second direction and crosses the first opening, each of the at least one second supporting portion comprises two second ends fixed to the frame, the second direction is different from the first direction.

13. The mask of claim 12, wherein the main film is a discontinuous layer and comprises at least two sub-layers; each of the at least one first supporting portion comprises a main portion and an extending portion extending from the main portion; the main portion supports two adjacent sub-layers, the extending portion locates between two adjacent sub-layers to separate the two adjacent sub-layers.

14. The mask of claim 1, wherein the plurality of second openings are arranged in an array.

15. The mask of claim 1, wherein a projection of the supporter on the main film does not overlap with the plurality of second openings.

16. The mask of claim 1, wherein the supporter is made of a magnetic metal or a magnetic alloy.

17. The mask of claim 1, wherein the frame is made of a magnetic metal or a magnetic alloy.
